(19) United States
(12) Patent Application Publication
(10) Pub. No.: US 2014/0372829 A1
(43) Pub. Date: Dec. 18, 2014

(54) RISK PROTECTION STORAGE DEVICE AND RISK PROTECTION METHOD THEREOF

(71) Applicant: Samsung Electronics Co., Ltd., Suwon-Si (KR)

(72) Inventors: Young-Jin PARK, Incheon (KR); Wonseok LEE, Suwon-si (KR); Hwajin JUNG, Hwaseong-si (KR)

(73) Assignee: Samsung Electronics Co., Ltd., Suwon-Si (KR)

(21) Appl. No.: 14/269,493

(22) Filed: May 5, 2014

(30) Foreign Application Priority Data
Jun. 14, 2013 (KR) 10-2013-0068504

(51) Int. Cl. G06F 11/10; H03M 13/11

(52) U.S. Cl. CPC G06F 11/10; H03M 13/1105
USPC 714/763

(57) ABSTRACT

A storage device in accordance with the inventive concepts includes at least one nonvolatile memory device and a memory controller controlling the nonvolatile memory device. The memory controller includes at least one processor configured to control an operation of the storage device, and configured to perform at least one of a trim operation according a trim command and a garbage collection operation and a risk protection controller configured to perform a risk protection operation that disables at least one of the garbage collection operation or the trim operation according to a risk protection signal internally generated or a risk protection command input from the external device.

### CROSS-REFERENCE TO RELATED APPLICATIONS

This U.S. non-provisional patent application claims priority under 35 U.S.C. §119 of Korean Patent Application No. 10-2013-0068504, filed on Jun. 14, 2013, the entire contents of which are incorporated herein by reference.

### BACKGROUND OF THE INVENTION

1. Field

At least some embodiments of the inventive concepts relate to a risk protection storage device and a risk protection method thereof.

2. Related Art

Generally, a semiconductor memory device can be classified into a volatile memory device such as a dynamic random access memory (DRAM), a static random access memory (SRAM), etc. and a nonvolatile memory device such as an electronically erasable programmable read-only memory (EEPROM), a ferroelectric random access memory (FRAM), a phase-change random access memory (PRAM), a magnetic random access memory (MRAM), a flash memory, etc. A volatile memory device loses its stored data when its power supply is interrupted but a nonvolatile memory device retains its stored data even when its power supply is interrupted. A flash memory has advantages including a high programming speed, low power consumption, a higher data storage capacity. Thus, a data storage device based on a flash memory is widely being used. Examples of a data storage device based on a flash memory include a solid state drive (SSD) replacing an existing hard disk and a memory card such as a Secure Digital (SD) card, a MultiMediaCard (MMC), etc.

### SUMMARY

According to at least some example embodiments, a storage device includes at least one nonvolatile memory device; and a memory controller configured to control the nonvolatile memory device, the memory controller including, at least one processor configured to control an operation of the storage device, and configured to perform at least one of a trim operation according a trim command and a garbage collection operation; a buffer memory configured to store data received from an external device to program the received data in at least one nonvolatile memory device in a write operation or store data read from the nonvolatile memory device to output the read data to the external device in a read operation; an error correction circuit configured to generate at least one error correction code corresponding to data stored in the buffer memory in the write operation or correct an error of the data read using at least error correction code in the read operation; and a risk protection controller configured to perform a risk protection operation that disables at least one of the garbage collection operation or the trim operation according to a risk protection signal internally generated or a risk protection command input from the external device.

According to at least some example embodiments, a risk protection method of a storage device which inputs and outputs data according to a request of a host includes performing a trim operation at the storage device according to a trim command; generating a risk protection command when a delete event occurs or a master boot record is accessed; and selectively disabling the trim operation according to the risk protection command.

According to at least some example embodiments, a storage device includes at least one nonvolatile memory device; and a memory controller configured to control the nonvolatile memory device, the memory controller including, at least one processor configured to control an operation of the storage device, and configured to perform a memory management operation on the at least one nonvolatile memory device, the memory management operation including at least one of a garbage collection operation and a trim operation, and a risk protection controller configured to perform a risk protection operation that disables the memory management operation in response to at least one of a risk protection signal generated internally by the storage device and a risk protection command received from an external device.

### BRIEF DESCRIPTION OF THE FIGURES

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram illustrating a first embodiment of a storage device in accordance with some embodiments of the inventive concepts.

FIG. 2 is a drawing for describing a risk protection operation when a performing a format operation of a storage device in accordance with some embodiments of the inventive concepts.

FIG. 3 is a drawing illustrating a risk protection operation when performing a format operation in accordance with some embodiments of the inventive concepts.

FIG. 4 is a drawing illustrating a risk protection operation when accessing a master boot record in accordance with some embodiments of the inventive concepts.

FIG. 5 is a drawing illustrating performing a risk protection operation on the basis of booting count in accordance with some embodiments of the inventive concepts.

FIG. 6 is a drawing illustrating a risk protection operation in accordance with a switch on/off operation according to some embodiments of the inventive concepts.

FIG. 7 is a drawing for conceptually describing a trim protection operation constituted by firmware in accordance with some embodiments of the inventive concepts.

FIG. 8 is a flow chart illustrating a risk protection method of a storage device in accordance with some embodiments of the inventive concepts.

FIG. 9 is a block diagram illustrating a second embodiment of a storage device in accordance with some embodiments of the inventive concepts.

FIG. 10 is a block diagram illustrating embedded multimedia card (eMMC) in accordance with some embodiments of the inventive concepts.

FIG. 11 is a block diagram illustrating a universal flash system (UFS) system in accordance with some embodiments of the inventive concepts.

FIG. 12 is a block diagram illustrating a mobile device in accordance with some embodiments of the inventive concepts.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Generally, a storage device makes an attempt to improve performance by processing invalid data through a garbage collection operation, a trim operation, etc. The garbage collection operation merges valid data of a memory block with other memory block and erases an original memory block. A garbage collection may be performed according to a policy of a storage device or an external command. A trim operation means that a memory block corresponding to invalidated data of a storage device is erased in advance to improve a speed of a next write operation. A trim operation will be described in detail in U.S. Pat. Nos. 7,802,054, 8,051,258, 8,122,193 and 8,122,198 and U.S. Patent Application Publications No. 2012-0144090 and 2012-0311237 assigned to Samsung Electronics Co., Ltd, the contents of which are herein incorporated by reference.

As described above, a garbage collection operation in a general storage device is immediately performed according a policy of a storage device or an external command and a trim operation is also immediately performed according to a trim command. For example, when a request for a format or file deletion event occurs in at least a portion of a storage device by a user, a garbage collection/trim operation is immediately performed. On this account, after a format/delete operation is performed by a mistake of a user or a virus, it may be difficult to restore data technically.

A storage device in accordance with some embodiments of the inventive concepts can perform a risk protection operation for protecting against a risk that may exist while a data processing operation such as a garbage collection operation or a trim operation is performed. The risk protection operation can be configured to control an activation (e.g., on/off status) of a garbage collection operation and a trim operation using various methods such as hardware, software and firmware.

According to at least some example embodiments, the inventive concepts are not limited to a garbage collection operation and a trim operation. According to at least some example embodiments, the inventive concepts can be applied to any data processing operation which is similar to a garbage collection operation and a trim operation.

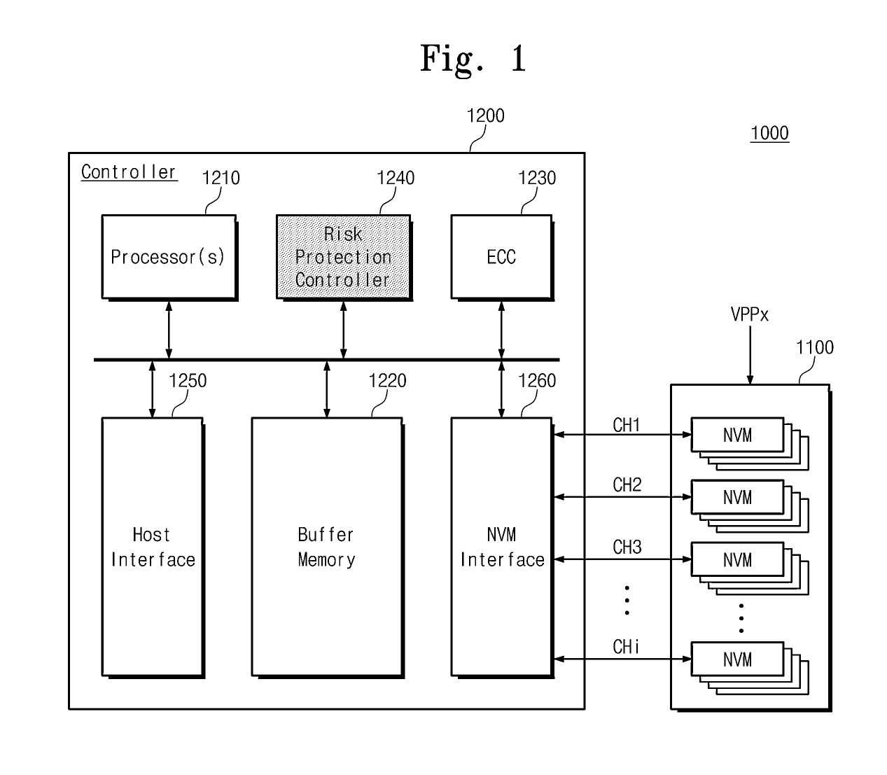

FIG. 1 is a block diagram illustrating a first embodiment of a storage device in accordance with some embodiments of the inventive concepts. Referring to FIG. 1, a storage device 1000 includes a plurality of nonvolatile memory devices 1100 and a memory controller 1200 controlling the nonvolatile memory devices 1100. Each of the nonvolatile memory devices 1100 may include one or more of a NAND flash memory, a vertical NAND flash memory (VNAND), a NOR flash memory, a resistive random access memory (RRAM), a phase change memory (PRAM), a magnetoresistive random access memory (MRAM), a ferroelectric random access memory (FRAM), a spin transfer torque random access memory (STT-RAM), etc.

Each of the nonvolatile memory devices 1100 can have a three-dimensional array structure. According to at least some example embodiments, the inventive concepts can be applied to not only a flash memory device of which a charge storage layer is constituted by a conductive floating gate but also a charge trap flash (CTF) of which a charge storage layer is constituted by an insulating layer. The nonvolatile memory devices 1100 can be optionally provided with an external high voltage Vpp.

The memory controller 1200 is connected to the nonvolatile memory devices 1100 through a plurality of channels CH1˜CHi (i is an integer of two or more). The memory controller 1200 includes one or more processors 1210, a buffer memory 1220, an error correction circuit 1230, a risk protection controller 1240, a host interface 1250 and a nonvolatile memory interface 1260.

The processor 1210 can control the whole operation of the storage device 1000. The buffer memory 1220 temporarily stores data needed to drive the memory controller 1200. The buffer memory 1220 temporarily stores data received from an external device when a write operation is performed to program it in the nonvolatile memory devices 1100 or temporarily stores data read from the nonvolatile memory devices 1100 when a read operation is performed to output it to an external destination. The buffer memory 1220 can include a plurality of memory lines that can store data or command. The memory lines can be mapped to cache lines which the processor 1210 directly accesses using various methods. The cache lines may exist inside the processor 1210 or may separately exist outside the processor 1210.

The error correction circuit 1230 can calculate an error correction code value of data to be programmed in a write operation, correct an error of data read in a read operation on the basis of the error correction code value and correct an error of data read from the nonvolatile memory device 1100 in a data restoration operation. Although not illustrated in FIG. 1, the storage device 1000 may further include a code memory storing code data needed to drive the memory controller 1200. The code memory can be embodied by a nonvolatile memory device (e.g., PRAM, MRAM, etc.).

The risk protection controller 1240 can perform a risk protection operation controlling an on/off of a garbage collection operation and a trim operation according to a risk protection signal which is internally generated or a risk protection command (or message) received from an external device.

A risk protection signal may occur in response to an on/off switch operation of a user with respect to a risk protection operation of the storage device 1000.

A risk protection signal can automatically occur when a format or file deletion request of a host occurs.

A risk protection signal may occur when a request for accessing a specific area of the storage device 1000 is received from an external device. The specific area may be, for example, a master boot recode (MBR).

A risk protection signal can occur when a garbage collection command or a trim command is received from an external device. When receiving a trim command, a risk protection signal may occur or not depending on a state of the storage device 1000.

A risk protection signal may occur when the number of memory blocks not being used in the storage device 1000 is more than a predetermined ratio.

The risk protection controller 1240 can temporarily delay or permanently cancel a garbage collection operation and a trim operation according to a risk protection signal which is internally generated.

A risk protection command can be embodied by a vendor command corresponding to a risk protection from an external host. For example, a risk protection command may be included in a format message being transmitted from an operating system driving a host to the storage device 1000.

A format event or a file deletion event is sensed by a specific program installed in a host and a risk protection command may occur or not depending on a sensing result. The specific program may be a firmware program for managing the storage device 1000.

A risk protection command may occur in a host according to user selection when a format event or a file deletion event occurs. According to at least some example embodiments, the inventive concepts are not limited only to a format event or a file deletion event. According to at least some example embodiments of the inventive concepts, a risk protection command may occur when various kinds of events for optimizing data of the storage device 1000 are performed to improve performance in a host.

A risk protection command may occur by user selection regardless of specific event occurrence. For example, when a user selects a disaster data reliability strengthen mode from a firmware program for managing the storage device 1000, a risk protection command may occur.

Although the storage device 1000 receives a risk protection command from an external device to perform a risk protection operation, the inventive concepts are not limited thereto. According to at least some example embodiments, the inventive concepts may receive a risk protection signal from an external device and may perform a risk protection operation according to the risk protection signal. At this time, the risk protection signal can be transmitted through a specific line between a host and the storage device 1000.

The risk protection controller 1240 can temporarily delay or permanently cancel a garbage collection operation and a trim operation according to a risk protection command received from an external device.

The risk protection controller 1240 can be embodied in at least one of hardware, software and firmware. That is, the risk protection controller 1240 can perform a risk protection operation in hardware, software and firmware. For example, the risk protection controller 1240 may be software for performing a risk protection operation by hooking a format command received from an external device.

The host interface 1250 can provide an interface function with an external device. The nonvolatile memory interface 1260 can provide an interface function with the nonvolatile memory device 1100.

The storage device 1000 can greatly reduce a risk with respect to a data restoration barrier, which may be caused by at least one of a garbage collection operation and a trim operation, by including the risk protection controller 1240.

Various embodiments for a risk protection operation of the inventive concepts related to a trim operation will be described below.

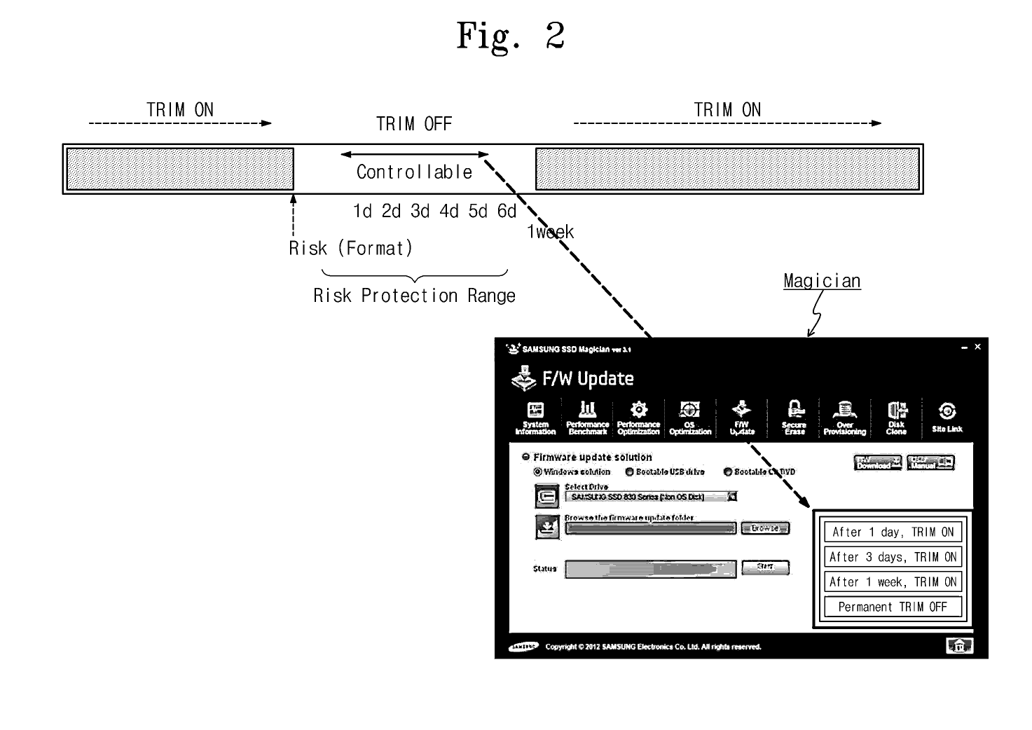

FIG. 2 is a drawing for describing a risk protection operation when a performing a format operation of a storage device in accordance with some embodiments of the inventive concepts. Referring to FIG. 2, if a format operation is performed while performing a trim on operation, the storage device 1000 performs a trim off operation. The trim on operation refers to a trim operation that is immediately started according to a received trim command.

A trim off section, that is, a risk protection section can be controlled by user selection. A user can perform a format operation on at least a portion of the storage device 1000 by a magician program for managing the storage device 1000. According to at least one example embodiment, a magician program may be any program that performs at least one of managing, updating, and optimizing a memory device. According to at least one example embodiment, the magician program is installed in an external operation system and can manage the storage device 1000 in firmware. Before starting a format operation, a user can select a risk protection section by the magician program. For example, a user can select a trim on start time when a format operation is performed. For example, a user can select so that a trim operation starts after one day, two days or one week, or does not start permanently by the magician program.

A trim on operation can be performed again after a risk protection section.

A trim off operation can start on the basis of trim off information included in a format command (or message) by an operation system vender. That is, the storage device 1000 can perform a trim off operation on the basis of the transmitted trim off information.

A trim off operation can be controlled by a magician program by hooking a format command be provided from an operation system. A magician program can transmit trim off information to the storage device 1000 by sensing that a user pushes a start button related to a format.

In the case of using a format program of a third party not being provided by an operation system, a magician program can transmit trim off command to the storage device 1000 when discovering a format try by monitoring a format program and adding a format profile.

The storage device 1000 can perform a risk protection operation controlling an activation (e.g. turning on/off) of a trim operation when a format operation is performed.

A risk protection operation can start by sensing a format, a fast format or a disk initialization operation with respect to a drive (looking at the storage device 1000 from the viewpoint of a host) in an operating system (e.g., windows, MAC, Linux, . . . ).

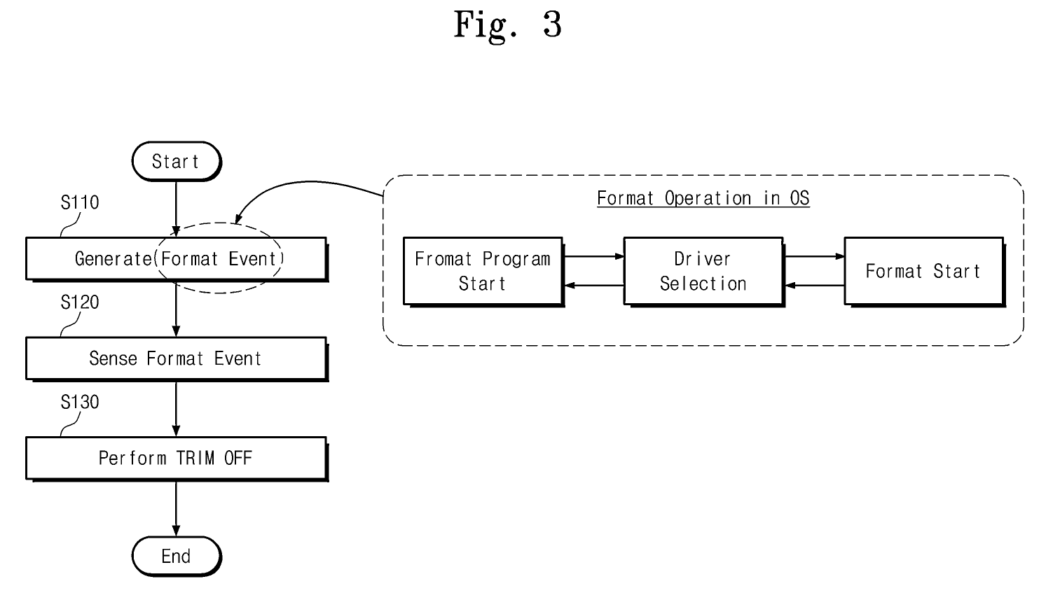

FIG. 3 is a drawing illustrating a risk protection operation when performing a format operation in accordance with some embodiments of the inventive concepts. Referring to FIGS. 1 through 3, in the case of performing a format operation in an operation system, a format event may occur. The format event may be one of a format program start, selection for driver to be formatted and format of the selected driver (S110). A magician program for managing the storage device 1000 can sense the format event using a hooking technology (S120). For example, a magician program can sense that a user clicks a format start button, clicks the formatted driver selection button or clicks a format start button in an operation system. If a magician program senses a format event, a trim off is performed on the storage device 1000 (S130).

According to at least some example embodiments, the inventive concepts can perform a risk protection operation by sensing a format event when a format operation is performed on an operation system.

According to at least some example embodiments, the inventive concepts are not limited to sensing a format event. According to at least some example embodiments, the inventive concepts can include a risk protection command (or message) in a format command by an operation system vender. The storage device 1000 can perform a risk protection operation according to a risk protection command transmitted together with a format command.

A risk protection operation can start when performing an access to a specific area of the storage device 1000, for example, a master boot recode (MBR), from an external device (a host).

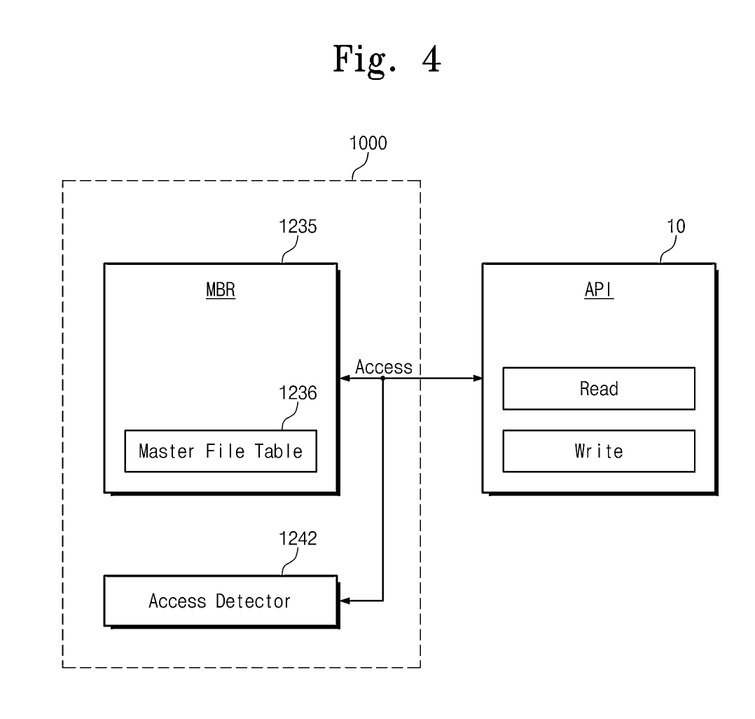

FIG. 4 is a drawing illustrating a risk protection operation when accessing a master boot record in accordance with some embodiments of the inventive concepts. Referring to FIG. 4, when an external application processor interface (API) 10 performs an access (a read or write operation) to a master boot record 1235 of the storage device, an access detector 1242 detects the access to generate a risk protection command. The access detector 1242 can generate a risk protection command in response to a read or write request with respect to a master file table (MFT) 1236 among the master boot recode (MBR).

Determining whether or not a format is performed may be accomplished by monitoring a disk boot sector access in an operation system. For example, when the monitoring sense an operation to delete a master file table (MFT) area or a delete message with respect to a master file table (MFT) area is generated, a trim off command may be generated.

When monitoring a disk boot sector access or requesting a change of a new technology file system (NTFS) size and header in a basic input/output system (BIOS), a trim off command may be generated.

According to at least some example embodiments, a risk protection operation of the inventive concepts can start on the basis of a booting count when an operation of the storage device 1000 having an elevated risk occurs (for example, when a format command is input).

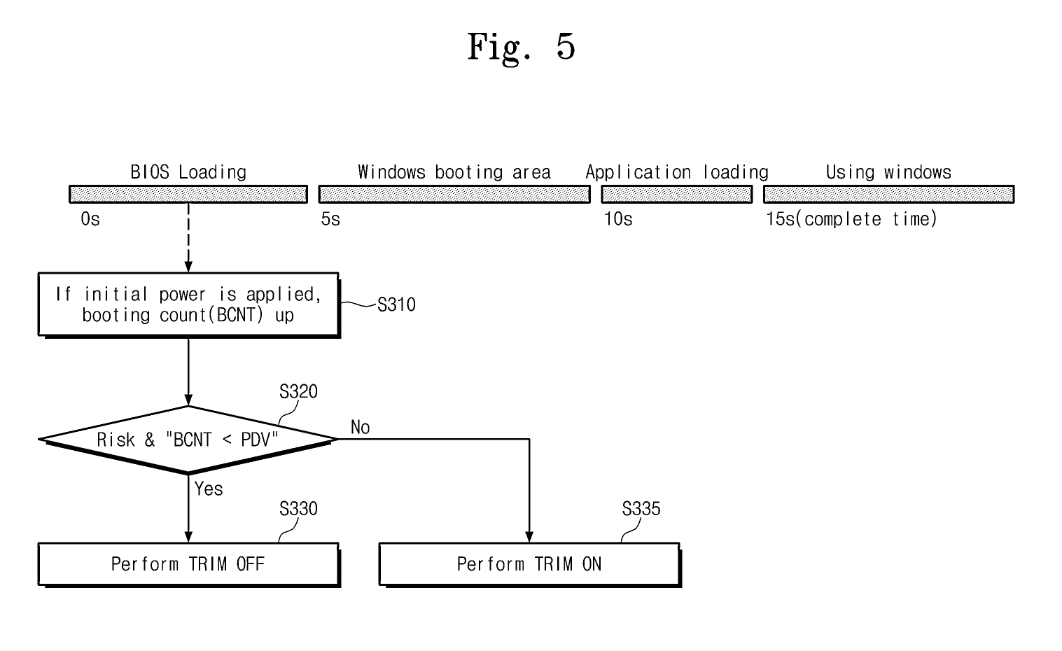

FIG. 5 is a drawing illustrating performing a risk protection operation on the basis of booting count in accordance with some embodiments of the inventive concepts. Referring to FIG. 5, after occurrence of a risk, the storage device 1000 increases booting count BCNT and stores the booting count value whenever initial power is applied (S310). After that, after an operation having an elevated risk (e.g., a format, a fast format and a disk initialization) occurs, the risk protection controller 1240 can distinguish whether the booting count BCNT value is smaller than a predetermined value PDV (S320). If the booting count BCNT value is smaller than a predetermined value PDV, a trim off operation is performed (S330). If the booting count BCNT value is not smaller than a predetermined value PDV, a trim on operation is performed (S335).

At least some example embodiments of the inventive concepts can perform a risk protection operation on the basis of the booting count after occurrence of a operation having an elevated risk.

A risk protection operation can start according to a switch on/off operation of a user.

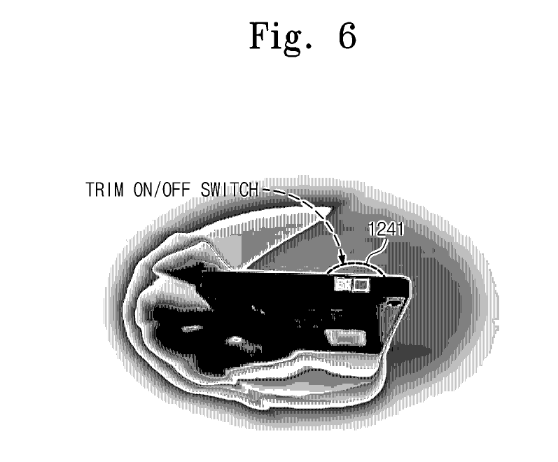

FIG. 6 is a drawing illustrating a risk protection operation in accordance with a switch on/off operation according to some embodiments of the inventive concepts. Referring to FIG. 6, the storage device 1000 may include a trim on/off switch 1241. A user can handle the trim on/off switch as needed. For example, if a user chooses to increase reliability with respect to data restoration, the user can handle the trim on/off switch 1241 so that a trim on operation is performed.

At least some example embodiments of the inventive concepts can perform a risk protection operation according to switch selection of a user.

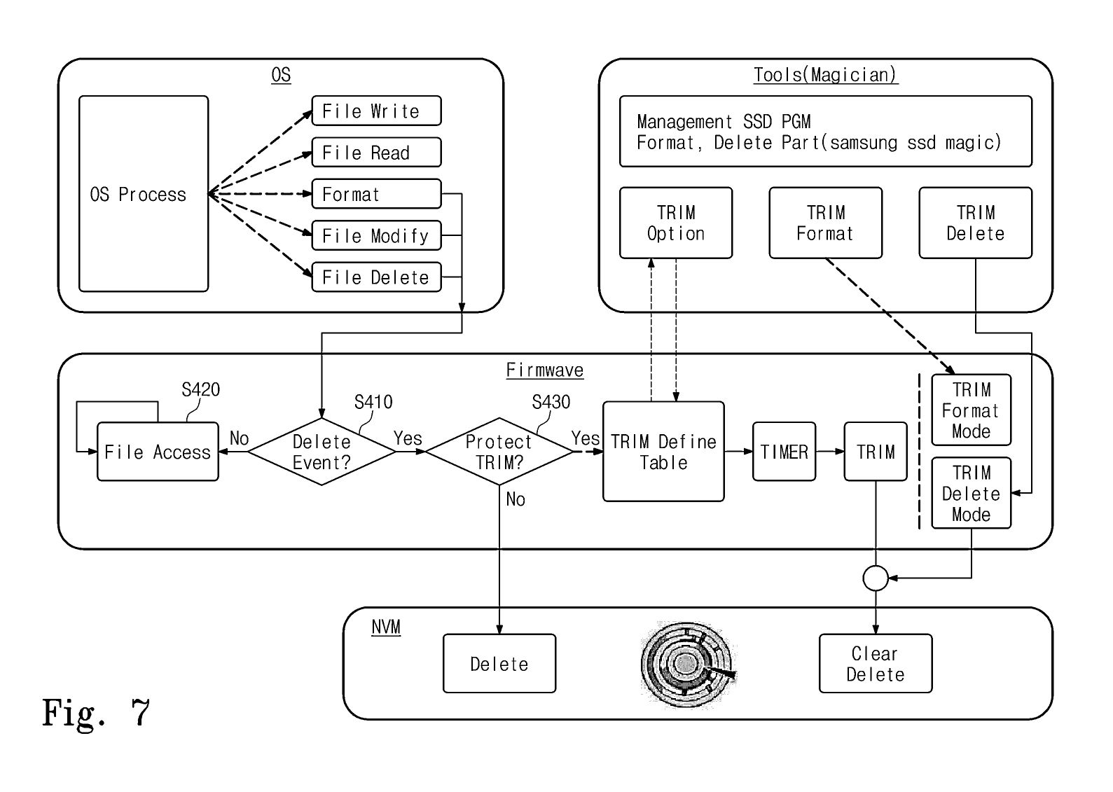

FIG. 7 is a drawing for conceptually describing a trim protection operation constituted by firmware in accordance with some embodiments of the inventive concepts. Referring to FIGS. 1 through 7, a trim protection operation will be performed, for example on the nonvolatile memory device 1100, as follows. A firmware senses a format command, a file change command, or a file delete command among operations being processed in an operation system (S410). If the sensed operation is not a delete event (format or file delete), a file access is performed (S420). If the sensed operation is a delete event (format or file delete), a firmware distinguishes whether an operation mode is a trim protection operation (i.e., a risk protection operation) (S430).

According to at least one example embodiment, if the operation mode is not a trim protection operation, a delete event is immediately performed on the nonvolatile memory devices 1100 of the storage device 1000. If the operation mode is a trim protection operation, a trim option with respect to a delete event is determined by searching a trim define table. The trim option includes trim time information indicating that after predetermined time elapses after a delete event, a trim operation is performed. The trim option may be set by a user using a magician program that manages the storage device 1000.

A timer judges whether predetermined time elapses on the basis of time information on the delete event. If predetermined time elapsed, a trim operation can be performed. A trim operation may be differently performed depending on a trim format mode and a trim delete mode. The trim mode can be set by a user by a storage device management means (for example, a magician program). For example, a trim format mode may be set to start a trim operation on memory blocks corresponding to a format after one week. A trim format mode may be set to start a trim operation on memory blocks corresponding to a file deletion after two days.

The firmware according to at least some embodiments of the inventive concepts can perform activation or deactivation of a trim operation depending on whether a delete event occurs and can determine a start of a trim operation according to a trim mode.

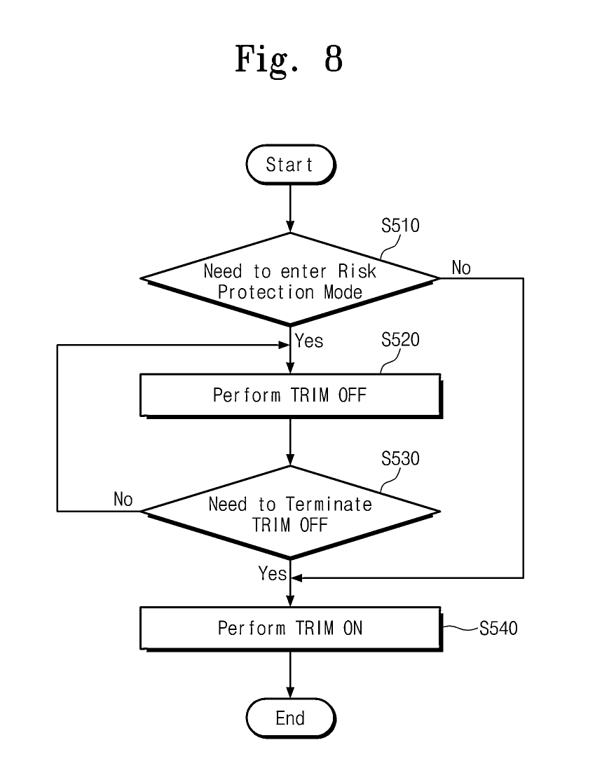

FIG. 8 is a flow chart illustrating a risk protection method of a storage device in accordance with some embodiments of the inventive concepts. Referring to FIGS. 1 through 8, a risk protection method is as follows. The risk protection controller 1240 of the storage device 1000 judges whether or not a risk protection mode needs to be entered (S510).

If a risk protection modemed needs to be entered, a trim off operation is temporarily performed (S520). After that, the risk protection controller 1240 judges whether or not the trim off operation needs needed to terminated (S530). If the trim off operation does not need to be terminated, the step S520 is maintained. If the trim off operation does not need to be terminated, a trim on operation is performed. In the step S510, if it is determined that the risk protection mode does not need to be entered, a trim on operation is performed (S540).

The risk protection method according to at least some example embodiments of the inventive concepts can determine whether to prevent or allow a trim operation depending on whether to enter a risk protection mode. In FIGS. 2 through 8, a risk protection operation related to a trim operation was described. However, the inventive concepts are not necessarily limited thereto. According to at least some example embodiments, the inventive concepts can be applied to a risk protection operation related to a garbage collection operation using similar methods, for example the same methods described above with respect to the trim operation.

In FIGS. 1 through 8, the risk protection controller 1240 for performing a risk protection operation exists outside the processor 1210. However, the inventive concepts are not necessarily limited thereto. The risk protection controller according to at least some example embodiments of the inventive concepts can be embodied inside the processor using various methods.

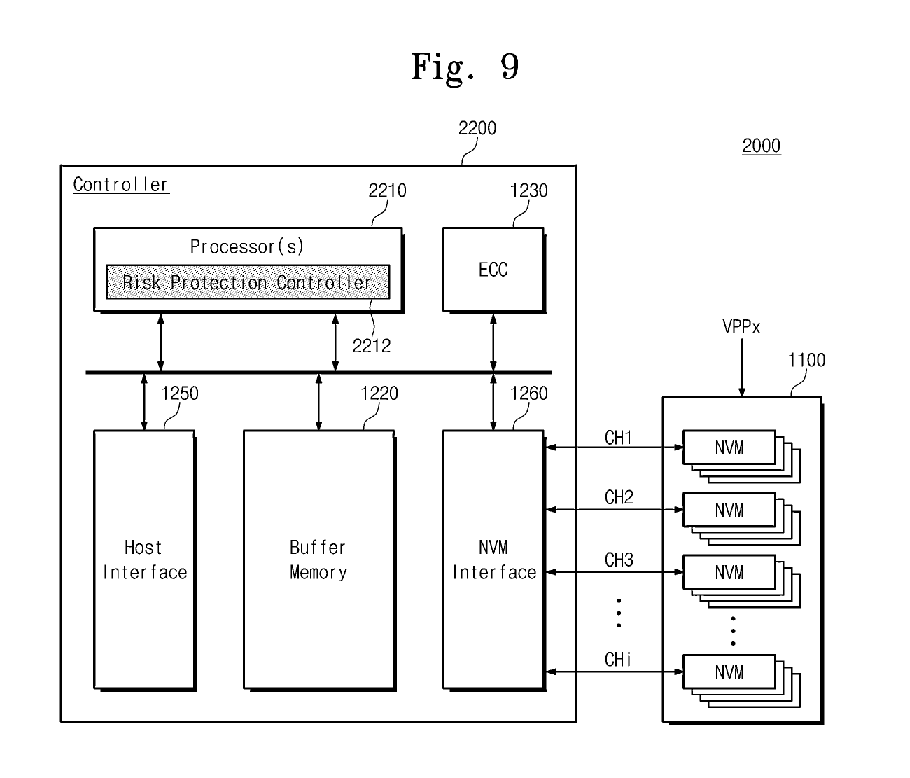

FIG. 9 is a block diagram illustrating a second embodiment of a storage device in accordance with some embodiments of the inventive concepts. Referring to FIG. 9, a storage device 2000 includes nonvolatile memory devices 2100 and the memory controller 2200 controlling the nonvolatile memory devices 2100. The memory controller 2200 has the same structure as the storage device 1000 illustrated in FIG. 1 except a processor 2210 including a risk protection controller 2212.

According to at least some example embodiments, the inventive concepts can be applied to embedded multimedia card (eMMC) (e.g., moviNAND, INAND) and can be applied to all kinds of products performing a function the same as, or similar to, a garbage collection/trim operation on a nonvolatile memory such as a SD card.

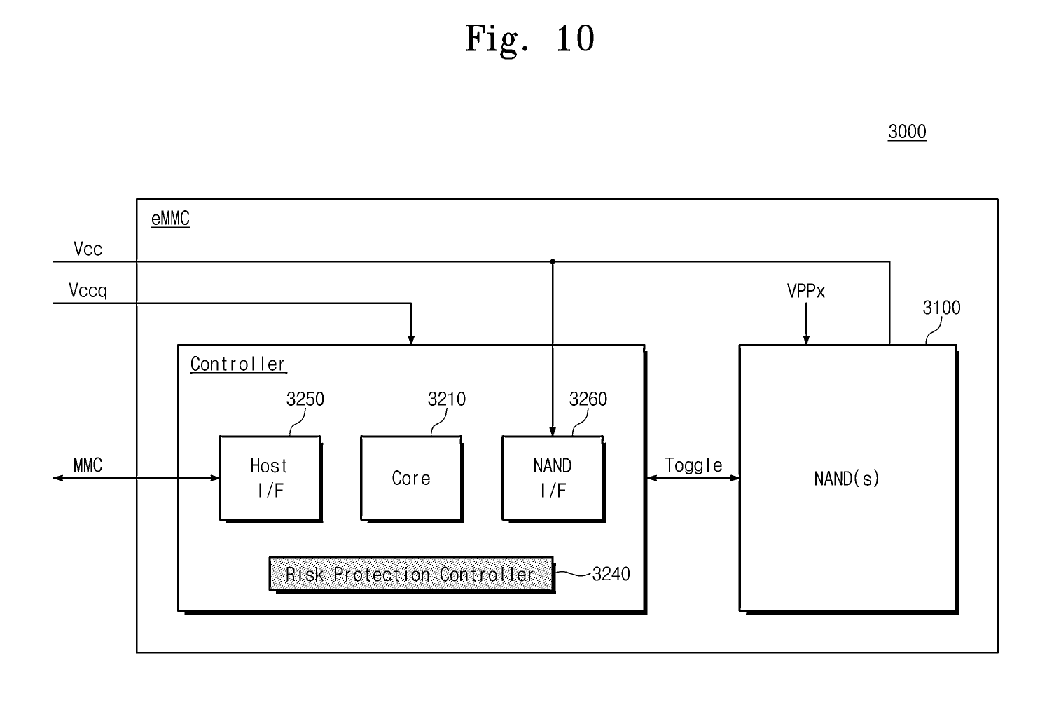

FIG. 10 is a block diagram illustrating eMMC in accordance with some embodiments of the inventive concepts. Referring to FIG. 10, eMMC 3000 includes at least one NAND flash memory device 3100 and a memory controller 3200.

The NAND flash memory device 3100 may be a single data rate (SDR) NAND or a double data rate (DDR) NAND. The memory controller 3200 is connected to the NAND flash memory device 3100 through a plurality of channels. The memory controller 3200 includes at least one controller core 3210, a risk protection controller 3240, a host interface 3250 and a NAND interface 3260. The controller core 3210 controls the whole operation of the eMMC 3000. The risk protection controller 3240 can be embodied to perform the risk protection operation described in FIGS. 1 through 9. The risk protection operation can be embodied in hardware, software or firmware. The host interface 3250 performs an interface between the controller 3210 and a host. The NAND interface 3260 performs an interface between the NAND flash memory device 3100 and the memory controller 3200. The host interface 3250 may be a parallel interface (e.g., MMC interface). In other embodiment, the host interface 3250 of the eMMC 3000 may be a serial interface (e.g., UHS-II, UFS interface).

The eMMC 3000 is provided with supply voltages (Vcc, Vccq) from a host. A first supply voltage Vcc (e.g., 3.3V) is provided to the NAND flash memory device 3100 and the NAND interface 3230. A second supply voltage Vccq (e.g., 1.8V/3.3V) is provided to the memory controller 3200. The eMMC 3000 can optionally receive an external high voltage Vpp.

The eMMC 3000 can improve reliability of data by performing a risk protection operation.

According to at least some example embodiments, the inventive concepts can be applied to a universal flash storage (UFS).

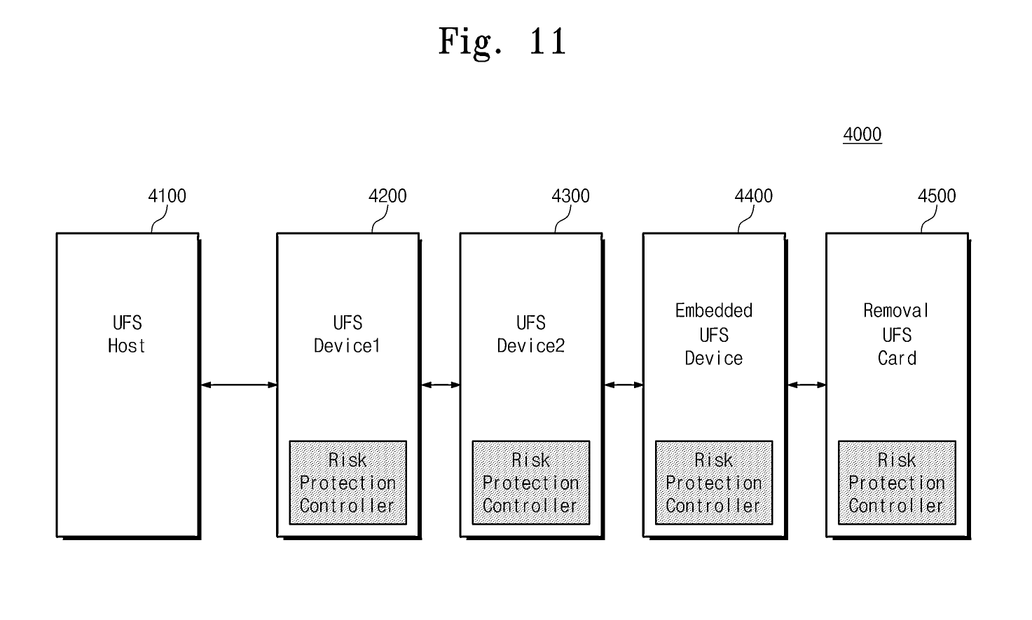

FIG. 11 is a block diagram illustrating a UFS system in accordance with some embodiments of the inventive concepts. Referring to FIG. 11, a UFS system 4000 may include a UFS host 4100, UFS devices 4200 and 4300, an embedded UFS device 4400 and a removal UFS card 4500. The UFS host 4100 may be an application processor of a mobile device. Each of the UFS host 4100, the UFS devices 4200 and 4300, the embedded UFS device 4400 and the removal UFS card 4500 can communicate with external devices using a UFS protocol. At least one of the UFS devices 4200 and 4300, the embedded UFS device 4400 and the removal UFS card 4500 is configured to perform the risk protection operation described in FIGS. 1 through 9.

The embedded UFS device 4400 and the removal UFS card 4500 can communicate with each other by other protocol which is not the UFS protocol. The UFS host 4100 and the removal UFS card 4500 can communicate with each other by various card protocols (e.g., UFDs, MMC, SD (secure digital), mini SD, micro SD).

According to at least some example embodiments, the inventive concepts can be applied to a mobile device.

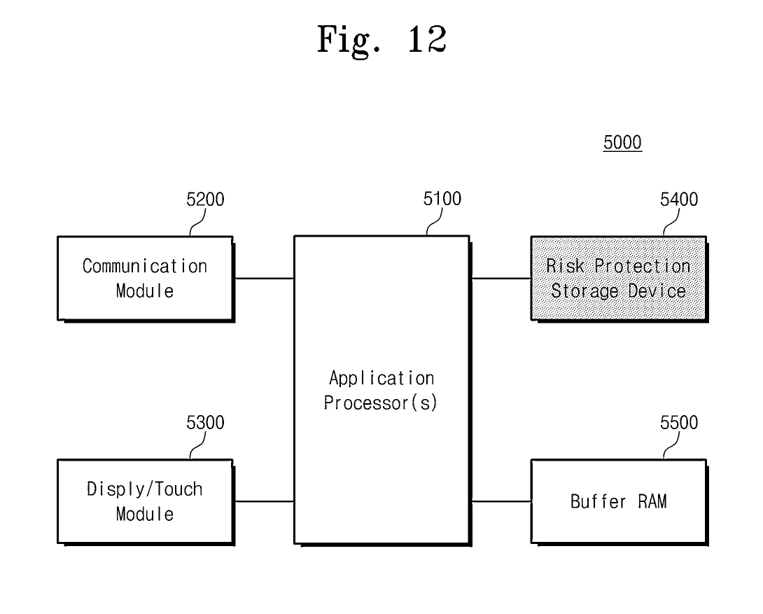

FIG. 12 is a block diagram illustrating a mobile device in accordance with some embodiments of the inventive concepts. Referring to FIG. 12, a mobile device 5000 includes an application processor 5100, a communication module 5200, a display/touch module 5300, a risk protection storage device 5400 and a mobile RAM 5500.

The application processor 5100 controls the whole operation of the mobile device 5000. The communication module 5200 is configured to control a wired/wireless communication with an external device. The display/touch module 5300 is configured to display data processed by the application processor 5100 or receive data from a touch panel. The risk protection storage device 5400 is configured to store data of a user. The risk protection storage device 5400 may be an eMMC, solid state drive (SSD) or UFS device. The risk protection storage device 5400 is embodied to include a nonvolatile memory device performing the risk protection operation described in FIGS. 1 through 9. The mobile RAM 5500 is configured to temporarily store data that is needed when performing a processing operation of the mobile device 5000.

The mobile device 5000 according to at least some embodiments of the inventive concepts can improve reliability of data when disturbance is generated by including the storage device 5400 performing a risk protection operation.

The memory system or the storage device in accordance with some embodiments of the inventive concepts can be mounted using one or more of various types of packages including, for example PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP) and wafer-level processed stack package (WSP).

As described above, the storage device and a risk protection method thereof in accordance with some embodiments of the inventive concepts can improve reliability with respect to data restoration by controlling an on/off of a garbage collection/trim operation when a risk occurs.

Although a some embodiments of the inventive concepts have been shown and described, it will be appreciated by those skilled in the art that changes may be made in these embodiments without departing from the principles and spirit of the inventive concepts, Such variations are not to be regarded as a departure from the intended spirit and scope of example embodiments, and all such modifications as would be obvious to one skilled in the art are intended to be included within the scope of the following claims.

What is claimed is:

1. A storage device comprising:
at least one nonvolatile memory device; and
a memory controller configured to control the nonvolatile memory device,
the memory controller including,
at least one processor configured to control an operation of the storage device, and configured to perform at least one of a trim operation according a trim command and a garbage collection operation;
a buffer memory configured to store data received from an external device to program the received data in at least one nonvolatile memory device in a write operation or store data read from the nonvolatile memory device to output the read data to the external device in a read operation;
an error correction circuit configured to generate at least one error correction code corresponding to data stored in the buffer memory in the write operation or correct an error of the data read using at least error correction code in the read operation; and
a risk protection controller configured to perform a risk protection operation that disables at least one of the garbage collection operation or the trim operation according to a risk protection signal internally generated or a risk protection command input from the external device.

2. The storage device of claim 1, further comprising:
a switch configured to generate the risk protection signal in response to user operation.

3. The storage device of claim 1, wherein the storage device is configured to generate the risk protection signal when a format operation is performed on at least a part of the storage device.

4. The storage device of claim 3, wherein the storage device is configured such that the risk protection controller is configured to perform the risk protection operation according to the risk protection command, and the storage device receives, from an external operation system managing the storage device, a format command corresponding to at least one of a format operation and a disk initialization operation, the risk protection command being included in the format command.

5. The storage device of claim 3, wherein the storage device is configured such that the risk protection controller is configured to perform the risk protection operation according to the risk protection command, and the risk protection command is received from a first program when the first program senses an upcoming format event that includes performing a format operation on at least part of the storage device, the first program being a program that is installed in an external operation system and manages the storage device using firmware.

6. The storage device of claim 1, further comprising:
an access sensor configured to generate the risk protection signal when a specific area of the storage device is accessed from the external device.

7. The storage device of claim 1, wherein the specific area is a master boot recode (MBR).

8. The storage device of claim 1, wherein the storage device is configured such that a trim off section in which the trim operation is disabled is selectively set by a user.

9. The storage device of claim 8, wherein the storage device is configured such that the risk protection controller is embodied in the memory controller using firmware, and
wherein the storage device is configured such that the firmware determines whether to perform the risk protection operation according to a format command, a file change command or a file delete command generated from an external operation system managing the storage device and the firmware performs the risk protection operation according to a trim operation mode set by a user using a management magician program managing the storage device.

10. The storage device of claim 9, wherein the storage device is configured such that the trim operation mode comprises:
a trim format mode for performing a format operation, and
a trim delete mode for performing a file deletion.

11. The storage device of claim 1, wherein the storage device is configured such that the risk protection operation starts on the basis of booting count after a risk occurs.

12. The storage device of claim 1, wherein the storage device is one of a solid state drive (SSD), an embedded multimedia card (eMMC) and a secure Digital (SD) card.

13. A risk protection method of a storage device which inputs and outputs data according to a request of a host, the risk protection method comprising:
performing a trim operation at the storage device according to a trim command;
generating a risk protection command when a delete event occurs or a master boot record is accessed; and
selectively disabling the trim operation according to the risk protection command.

14. The risk protection method of claim 13, wherein the selective disabling of the trim operation includes disabling the trim operation temporarily during a reference time according to the risk protection command.

15. The risk protection method of claim 13, wherein the selective disabling of the trim operation includes disabling the trim operation permanently according to the risk protection command.

16. A storage device comprising:
at least one nonvolatile memory device; and
a memory controller configured to control the nonvolatile memory device,
the memory controller including,
at least one processor configured to control an operation of the storage device, and configured to perform a memory management operation on the at least one nonvolatile memory device, the memory management operation including at least one of a garbage collection operation and a trim operation, and
a risk protection controller configured to perform a risk protection operation that disables the memory management operation in response to at least one of a risk protection signal generated internally by the storage device and a risk protection command received from an external device.

17. The storage device of claim 16, further comprising:
a buffer memory configured to perform at least one of,
storing, for a data write operation, data received from an external device to be written to the at least one nonvolatile memory device, and
storing, for a data read operation, data read from the nonvolatile memory device.

18. The storage device of claim 16, further comprising:
an error correction circuit configured to perform at least one of,
generating, for a data write operation, at least one error correction code corresponding to the data stored in the buffer memory for the data write operation, and
correcting, for a data read operation, an error of the data read from the nonvolatile memory device using at least one error correction code.
